(19) United States
(12) Patent Application Publication
(10) Pub. No.: US 2013/0102109 A1
(43) Pub. Date: Apr. 25, 2013

(54) METHOD AND APPARATUS OF REMOVING A PASSIVATION FILM AND IMPROVING CONTACT RESISTANCE IN REAR POINT CONTACT SOLAR CELLS

(71) Applicant: Applied Materials, Inc., Santa Clara, CA (US)

(72) Inventors: Michael P. Stewart, San Francisco, CA (US); Hari K. Ponnekanti, San Jose, CA (US); Prabhat Kumar, Fremont, CA (US); Jeffrey L. Franklin, Albuquerque, NM (US); Kapila P. Wijekoon, Palo Alto, CA (US)

(73) Assignee: Applied Materials, Inc., Santa Clara, CA (US)

(21) Appl. No.: 13/655,170

(22) Filed: Oct. 18, 2012

Related U.S. Application Data
(60) Provisional application No. 61/550,811, filed on Oct. 24, 2011.

(51) Int. Cl. H01L 31/18

(52) U.S. Cl. 438/98; 156/345.21; 257/E31.124

(57) ABSTRACT

Embodiments of the present invention generally provide improved processes and apparatus for removing passivation layers from a surface of photovoltaic cells and improving contact resistance in rear point contact photovoltaic cells. In one embodiment, a method of processing a solar cell substrate includes providing a substrate having a passivation layer deposited on a first surface of the substrate. The passivation layer is a layer stack comprising an aluminum oxide and a silicon nitride. The method also includes exposing the first surface of the substrate to an etchant, and heating the etchant to dissolve the aluminum oxide of the passivation layer on the first surface. The method may further include forming a metal containing layer on a second surface of the substrate that is opposite to the first surface.

### CROSS-REFERENCE TO RELATED APPLICATIONS

This application claims benefit of U.S. provisional patent application Ser. No. 61/550,811, filed Oct. 24, 2011, which is herein incorporated by reference.

### BACKGROUND

1. Field of the Invention

Embodiments of the present invention generally relate to improved processes and apparatus for removing passivation layers from a surface of photovoltaic cells and improving contact resistance in rear point contact photovoltaic cells.

2. Description of the Related Art

Solar cells are photovoltaic devices that convert sunlight directly into electrical power. The most common solar cell material is silicon (Si), which is in the form of single crystalline, polycrystalline or multi-crystalline substrates. Because the cost of electricity generated using silicon-based solar cells is higher than the cost of electricity generated by traditional methods, there has been an effort to reduce the cost of manufacturing solar cells that does not adversely affect the overall efficiency of the solar cell.

When light falls on the solar cell, energy from the incident photons generates electron-hole pairs on both sides of the p-n junction region. Electrons diffuse across the p-n junction to a lower energy level and holes diffuse in the opposite direction, creating a negative charge on the n-type emitter and a corresponding positive charge builds up in the p-type base. When an electrical circuit is made between the emitter and the base and the p-n junction is exposed to certain wavelengths of light, a current will flow. The electrical current generated by the semiconductor when illuminated flows through front contacts disposed on the front side, i.e. the light-receiving side, and back contacts disposed on the backside of the solar cell. The front contacts are generally configured as widely-spaced thin metal lines, or fingers, that supply current to a larger busbar. The back contacts are generally not constrained to be formed in multiple thin metal lines, since the back contacts do not block incident light from striking the solar cell.

Recombination occurs when electrons and holes, which are moving in opposite directions in a solar cell, combine with each other. Each time an electron-hole pair recombines in a solar cell, charge carriers are eliminated, thereby reducing the efficiency of the solar cell. Recombination is a function of how many dangling bonds, i.e., unterminated chemical bonds, are present on the surfaces of the substrate. Dangling bonds are found on surfaces because the silicon lattice of a substrate ends at these surfaces. These unterminated chemical bonds act as defect traps, which are in the energy band gap of silicon, and therefore are sites for recombination of electron-hole pairs.

In order to reduce surface recombination of electron-hole pairs, surfaces of the substrate may be passivated by forming a passivation layer thereon to reduce the number of dangling bonds present on the surface of the substrate. However, during deposition of the passivation layer, the material being deposited on one side of the substrate may also deposit on, and over the edge of the other side of the substrate, causing a color change in the appearance of the resulting solar cell module and also a product reliability risk.

In addition, solar cells with a rear passivation layer require a method of forming back metal contacts through the rear passivating layer. One way of creating back metal contacts through the rear passivation layer is to use a laser ablation technique to selectively remove the passivating layer from the back surface of the substrate, thereby forming a via/contact hole. Depending on the wavelength used in the laser ablation process, the condition and cleanliness of the via/contact holes may vary across the substrate surface. For example, defects or debris may be present in the ablated via/contact holes due to residual layer which was not completely ablated during the laser ablation process, damaged base region underneath the rear passivation layer, or both. These debris could interfere with the subsequent process of forming a back metal contact, causing a product reliability risk and also a contact resistance of the via/contact hole to suffer.

Therefore, there exists a need for improved processes and apparatus to remove a passivation layer and clean via/contact holes of a solar cell to improve product reliability.

### SUMMARY OF THE INVENTION

Embodiments of the invention generally relate to improved processes and apparatus for removing passivation layer(s) from a surface of photovoltaic cells and improving contact resistance in rear point contact photovoltaic cells. In one embodiment, a method of processing a solar cell substrate includes providing a substrate having a passivation layer deposited on a first surface of the substrate, the passivation layer being formed as a layer stack comprising an aluminum oxide and a silicon nitride, exposing the first surface of the substrate to an etchant, heating the etchant to dissolve the aluminum oxide of the passivation layer on the first surface, and forming a metal containing layer on a second surface of the substrate, the second surface being opposite to the first surface.

In another embodiment, the method of processing a solar cell substrate includes providing a substrate having a passivation layer deposited on a surface of the substrate, the passivation layer being formed as a layer stack comprising an aluminum oxide and a silicon nitride deposited on the aluminum oxide, forming a plurality of via/contact holes in the passivation layer to expose the underlying surface of the substrate, exposing the substrate to a first cleaning solution comprising a dilute acid solution to selectively remove a portion of silicon nitride present in the formed via/contact holes, and exposing the substrate to a second cleaning solution comprising a dilute alkaline solution to selectively remove a portion of aluminum oxide present in the formed via/contact holes.

In yet another embodiment, a processing system for processing a substrate is provided. The system includes a spraying chamber having a spray device configured to supply an etchant onto a first surface of the substrate, a heating chamber having a radiant heating source configured to heat the etchant to dissolve a passivation layer deposited on the first surface of the substrate, the passivation layer comprising aluminum oxide, a patterning chamber configured to deliver a pulsed laser scanning across a surface of a passivation layer deposited on a second surface of the substrate, the second surface being opposite to the first surface, and the passivation layer being formed as a layer stack comprising an aluminum oxide and a silicon nitride deposited on the aluminum oxide, a screen printing chamber configured to deposit a metal containing layer in a predetermined pattern on the passivation layer deposited on the second surface of the substrate, and a transport system for conveying the substrate through the spraying chamber, the heating chamber, the patterning chamber, and the screen printing chamber. In one example, the system may further include a cleaning chamber configured to sequentially remove a portion of the silicon nitride and the aluminum oxide from the second surface, the cleaning chamber comprising a first tank containing a dilute acid solution comprising hydrofluoric acid (HF) at a concentration of about 0.1% by volume to about 5% by volume, and a second tank containing a dilute alkaline solution comprising potassium hydroxide (KOH) at a concentration of about 0.5% by volume to about 5% by volume.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a schematic cross-sectional view of a solar cell having a passivation layer formed on a back surface of a substrate in accordance with one embodiment of the invention.

FIG. 1B depicts a cross sectional view of a crystalline silicon type solar cell substrate during a stage of the manufacturing process depositing the passivation layer on the back surface of the substrate.

FIG. 2 depicts a schematic top plan view illustrating a portion of an in-line processing system for processing solar cell substrates depicted in FIG. 1A according to embodiments of the present invention.

FIG. 3 depicts an exemplary spraying chamber with a spray device disposed above a substrate placed on an incoming conveyor according to one embodiment of the present invention.

FIG. 4A depicts a side view of a squeegee applying etchant onto a front surface of a substrate using a printing device according to one embodiment of the present invention.

FIG. 4B depicts a schematic top view of the printing device of FIG. 4A according to one embodiment of the present invention

FIG. 5 depicts an exemplary process sequence used to remove a passivation layer from a front surface of a solar cell substrate according to one embodiment of the present invention.

FIG. 6 depicts an exemplary process sequence that may be optionally performed in the process sequence depicted in FIG. 5.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to improved processes and apparatus for removing passivation layer(s) from a surface of photovoltaic cells and improving contact resistance in rear point contact photovoltaic cells. In one embodiment, the invention contemplates utilizing a roller, stamp, squeegee, or other soft contact tool to apply an etchant, which is chosen to be selective to a passivation layer over the underlying layer, to a surface of a crystalline silicon solar cell substrate. As will be discussed below in more detail, the etchant may be first applied to the substrate in one location at the front surface and then spread across the surface using the soft contact tool. Alternatively, the etchant may be applied to the roller, stamp, or squeegee itself and then onto substantially the entire front surface of the substrate by moving the substrate relative to the roller, stamp, or squeegee. The etchant is then heated in a heating chamber to a desired temperature to dissolve the undesired passivation layer at the periphery region of the substrate. Thereafter, the substrate is rinsed with water or deionized water to remove dissolved passivation layer from the front surface of the substrate.

In another embodiment, the invention contemplates a post-cleaning process which may be performed between a via opening process and a screen printing process. In cases where a passivation layer is formed as a layer stack comprising an aluminum oxide (Al₂O₃) and a silicon nitride (SiN), the substrate may be dipped in a dilute acid solution, such as hydrofluoric acid (HF), to selectively etch the silicon nitride residues present in the patterned via/contact holes. The silicon nitride residues are formed due to the incomplete ablation from the previous process. After the silicon nitride residues have been removed from the surface of the substrate, the underlying aluminum oxide is exposed. The substrate is then wet etched with a dilute alkaline solution, such as potassium hydroxide (KOH), to remove the aluminum oxide residues from the back surface of the substrate without significantly eroding the underlying p-type base region.

### Exemplary Solar Cell Device

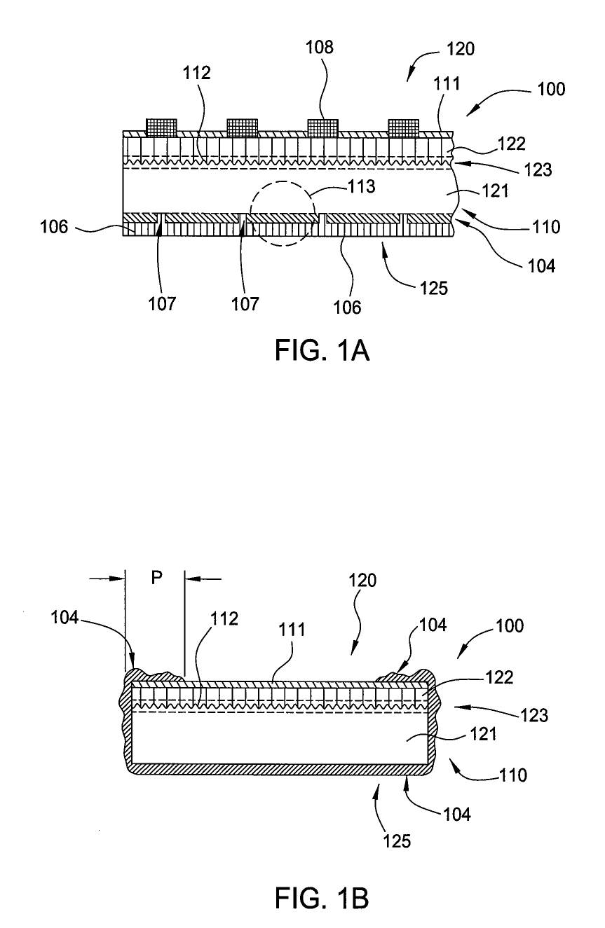

Solar cell substrates that may benefit from the invention include substrates that have an active region that contains single crystal silicon, multi-crystalline silicon, or polycrystalline silicon, but may also be useful for substrates comprising germanium (Ge), gallium arsenide (GaAs), cadmium telluride (CdTe), cadmium sulfide (CdS), copper indium gallium selenide (CIGS), copper indium selenide (CuInSe2), gallilium indium phosphide (GaInP2), organic materials, as well as heterojunction cells, such as GaInP/GaAs/Ge or ZnSe/GaAs/Ge substrates, that are used to convert sunlight to electrical power. FIG. 1A depicts a cross sectional view of a crystalline silicon type solar cell substrate, or substrate 110 that may have a passivation layer 104 formed on a surface, e.g. a back surface 125, of the substrate 110. In the embodiment depicted in FIG. 1A, a silicon solar cell 100 is fabricated on the crystalline silicon type solar cell substrate 110 having a textured surface 112. The substrate 110 generally includes a p-type base region 121, an n-type emitter region 122, and a p-n junction region 123 disposed therebetween. The n-type emitter region 122 may be formed by doping a deposited semiconductor layer with certain types of elements (e.g., phosphorus (P), arsenic (As), or antimony (Sb)) in order to increase the number of negative charge carriers, i.e., electrons. In the exemplary embodiment depicted in FIG. 1A, the n-type emitter region 122 is formed by use of an amorphous, microcrystalline, nanocrystalline, or polycrystalline CVD deposition process that contains a dopant gas, such as a phosphorus containing gas (e.g., PH₃). Therefore, a heterojunction type solar cell 100 having the p-n junction region 123 formed between the p-type base region 121 and the n-type emitter region 122 is formed. The electrical current is generated when light strikes a front surface 120 of the solar cell substrate 110. The electrical current flows through metal front contacts 108 and a metal backside contact 106 formed on a back surface 125 of the substrate 110.

A passivation layer 104 may be disposed between the back contact 106 and the p-type base region 121 on the back surface 125 of the solar cell 100. As discussed above, the passivation layer 104 may be a dielectric layer providing a good interface property that reduces the recombination of the electrons and holes, drives and/or diffuses electrons and charge carriers back to the junction region 123, and minimizes light absorption. The passivation layer 104 is disposed between the back contact 106 and the p-type base region 121 that allows a portion, e.g., via/contact holes 107, of the back contact 106 extending through the passivation layer 104 to be in electrical contact/communication with the underlying p-type base region 121. The front contacts 108 are generally configured as widely-spaced thin metal lines, or fingers, that supply current to larger buss bars transversely oriented relative to the via/contact holes 107. The back contact 106 is generally not constrained to be formed in multiple thin metal lines, since it does not prevent incident light from striking the solar cell 100. However, a plurality of via/contact holes 107 may be formed within the passivation layer 104 that are electrically connected to the back contact 106 to facilitate electrical flow between the back contact 106 and the p-type base region 121.

The passivation layer 104 may be an aluminum oxide (Al₂O₃) layer, an aluminum nitrite layer, or an aluminum oxynitride layer. Alternatively, the passivation layer 104 may be formed as a layer stack comprising silicon oxide, silicon nitride, aluminum oxide, aluminum nitride, aluminum oxynitride, amorphous silicon, or amorphous silicon carbide. In one example where a passivatioin layer stack is used, the passivation layer stack may include a silicon nitride deposited on an aluminum oxide layer (or vice versa). The silicon nitride may have a thickness of about 5 nm to about 100 nm. The aluminum oxide layer may have a thickness of about 5 nm to about 130 nm. In another example, the passivation layer stack may include a silicon dioxide of about 60 nm to about 250 nm in thickness deposited on an aluminum oxide layer of about 20 nm to about 130 nm in thickness (or vice versa). The silicon dioxide may have a thickness of about 60 nm to about 250 nm. The aluminum oxide may have a thickness of about 20 nm to about 130 nm. In either case, the thickness of the aluminum oxide layer and the silicon nitride is chosen such that the total thickness of the passivation layer stack is about 100 nm or more for effective reduction of surface recombination of electron-hole pairs. In one embodiment depicted in FIG. 1A, the passivation layer 104 is an aluminum oxide layer of about 20 nm to about 100 nm in thickness deposited by ALD process. ALD process has been proved to enable well controlled deposition rate and production of thin film coatings with nanometer-scaled thickness while providing an excellent level of surface passivation on low-resistivity p-type base region. However, it is contemplated that the passivation layer may be deposited by use of any other suitable deposition technique such as thermal or plasma assisted ALD (atomic layer deposition), PVD (physical vapor deposition), CVD (chemical vapor deposition), SACVD (sub-atmospheric chemical vapor deposition), or PECVD (plasma-enhanced chemical vapor deposition).

The front contacts 108 and/or back contact 106 may be a metal selected from a group consisting of aluminum (Al), silver (Ag), tin (Sn), cobalt (Co), nickel (Ni), zinc (Zn), lead (Pb), tungsten (W), titanium (Ti) and/or tantalum (Ta), nickel vanadium (NiV) or other similar materials. In one embodiment, the back contact 106 comprises aluminum (Al) material and nickel vanadium (NiV) material. Portion of the front contacts 108 and the back contact 106 may be disposed on the surfaces 120, 125 of the substrate 110 using a screen printing process performed in a screen printing tool, which is available from Baccini S.p.A, a subsidiary of Applied Materials, Inc. In one embodiment, the front contacts 108 and the back contact 106 are heated in an oven to cause the deposited material to densify and form a desired electrical contact with the substrate surface 120, 125. The solar cell 100 may be covered with a thin layer of a dielectric material to act as an anti-reflective coating (ARC) layer 111 that minimizes light reflection from the front surface 120 of the solar cell 100. In one example, the anti-reflective coating (ARC) layer may be selected from a group consisting of silicon nitride (SiₓN_{y}), silicon nitride hydride (SiₓN_{y}:H), silicon oxide, silicon oxynitride, a composite film stack of silicon oxide and silicon nitride, and the like.

FIG. 1B depicts a cross sectional view of a crystalline silicon type solar cell substrate, or substrate 110 during a stage of the manufacturing process depositing the passivation layer 104 on the back surface 125 of the substrate 110. Particularly, FIG. 1B illustrates a stage prior to the formation of the front contacts 108 and back contact 106 as depicted in FIG. 1A. During deposition of the passivation layer 104, the material being deposited on the back surface 125 may also deposit on, and over, the periphery region “P” of the front surface 120 of the substrate 110 with a thickness of about 20 nm, which unfavorably changes the appearance of the anti-reflective coating layer 111 that has already deposited on the front surface 120. The periphery region “P” may have a width ranging between about 5 nm and about 60 nm from the substrate edge. It has been observed that the optical characteristics (e.g., refractive index) of the anti-reflective coating layer 111 may also change especially when the passivation layer 104 wrapping around the front surface 120 of the substrate 110 in a non-uniform manner (FIG. 1B), which in turn causes the efficiency and long-term reliability of the solar cell to suffer. In order to overcome the above-mentioned issues, an improved process has been proposed by the inventors to selectively remove the passivation layer 104 from the undesired side (e.g., front surface 120) of the substrate 110, as will be discussed below.

### Exemplary Cleaning Process/Tool for Removal of a Passivation Layer

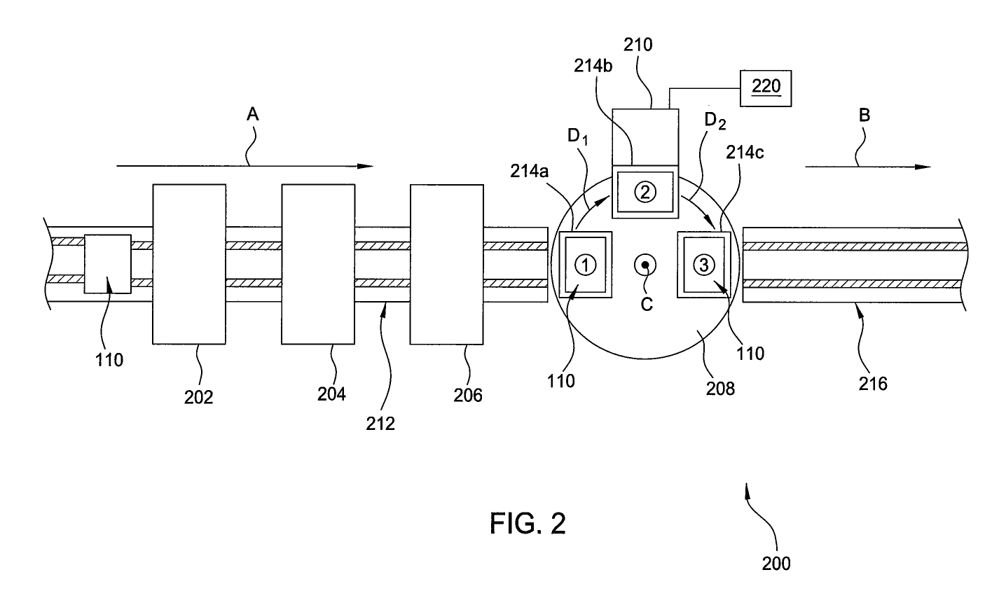

FIG. 2 depicts a schematic top plan view illustrating a portion of an in-line processing system 200 for processing solar cell substrates 110 depicted in FIG. 1A according to embodiments of the present invention. The in-line processing system 200 generally includes, among others, a spraying chamber 202, a heating chamber 204, a patterning chamber 206, a rotary actuator assembly 208, and a screen print chamber 210. An incoming conveyor 212 may be provided and configured to receive a substrate 110 from an input device (not shown) and transfer the substrate 110, following arrow “A”, through the spraying chamber 202, the heating chamber 204, the patterning chamber 206, and to a substrate support 214a coupled to the rotary actuator assembly 208. An outgoing conveyor 216 may be provided and configured to receive a substrate 110 from a substrate support 214c coupled to the rotary actuator assembly 208 and transfer the substrate 110 to a substrate removal device (not shown). While not shown, it is contemplated that the incoming conveyor 212 and the outgoing conveyor 216 may be automated substrate handling devices that are part of a larger production line. For example, the incoming conveyor 212 and the outgoing conveyor 216 may be part of the Softline™ tool, of which the system 200 may be a module.

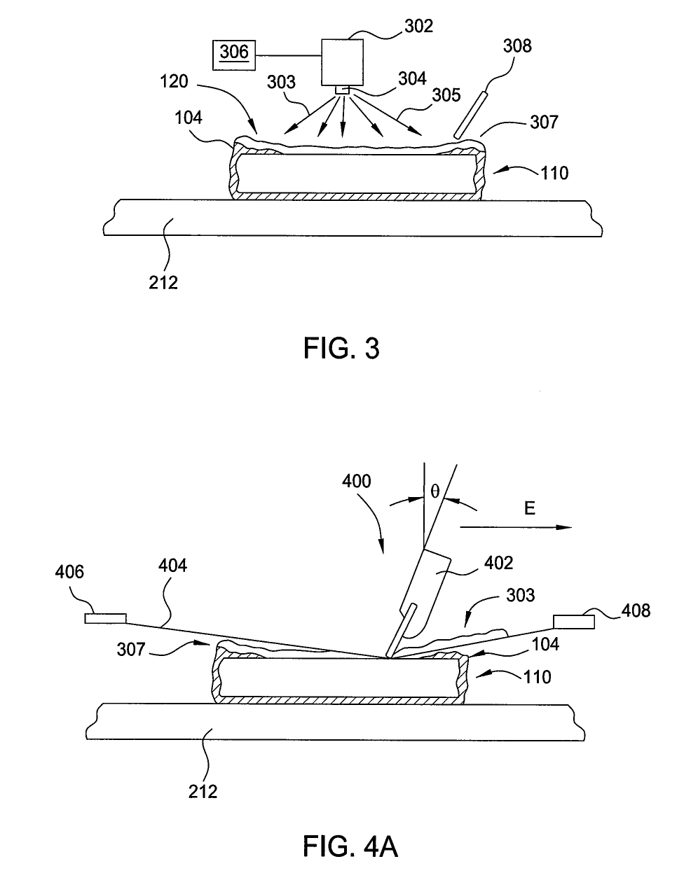

The spraying chamber 202 is configured in conjunction with the heating chamber 204 to remove the undesired passivation layer 104 from a surface (e.g., the front surface 120) of the substrate 110. In one embodiment shown in FIG. 3, the spraying chamber 202 is provided with a spray device 302 disposed at a position above the substrate 110. For clarity, the anti-reflective layer 111, the n-type emitter region 122, and the p-n junction region 123 have been omitted from FIG. 3. The spray device 302 may be a dispenser arm that is vertically adjustable with respect to the substrate 110. The spray device 302 may have one or more nozzles 304 that can be adjusted to direct etchant 303 and/or rinse water 305 at desired locations of the substrate 110. The etchant 303 contains a chemistry that is selective to the passivation layer over the anti-reflective layer 111, as further discussed below. While not shown, nozzles 304 can be selectively connected to one or more chemical sources and de-ionized water. The spray device 302 may be connected to a controller 306 to control the mixing ratio and flow rate from the one or more chemical sources to the nozzles 304.

During the process, the substrate 110 may be transported on the incoming conveyor 212 and traveled beneath the spray device 302 such that a desired location or the entire front surface 120 of the substrate 110 is covered by etchant 303 and/or rinse water 305. The spray device 302 may be configured to move relative to the substrate 110 by an actuator (not shown) to increase the efficiency of the process. For example, the spray device 302 may be moved in a direction opposite to the direction of the substrate movement. After the etchant 303 has been distributed on the front surface 120 of the substrate 110, a soft contact tool 308 may be optionally used to spread out the etchant 303 on the front surface 120, thereby forming a thin etchant layer 307 on the front surface 120.

The soft contact tool 308 may be a blade, squeegee, brush, roller, or the like. In cases where a roller is used, the etchant 303 may be first applied to the front surface 120 of the substrate 110 in one location and then spread across the entire front surface 120 using the roller, or the etchant 303 may be applied to the roller and then spread onto the entire front surface 120 of the substrate 110. The etchant 303 may be applied onto substantially the entire front surface 120 of the substrate 110 through linear and/or circular movement of the roller. While the substrate 110 is described to move pass the spray device 302 by use of the incoming conveyor 212, the present invention also contemplates the use of a rotary table or a X-Y stage so that the substrate 110 may be rotated or moved relative to the spray device 302 while the soft contact tool 308 is in contact with the substrate 110, thereby spreading etchant 303 across the entire front surface 120 of the substrate 110.

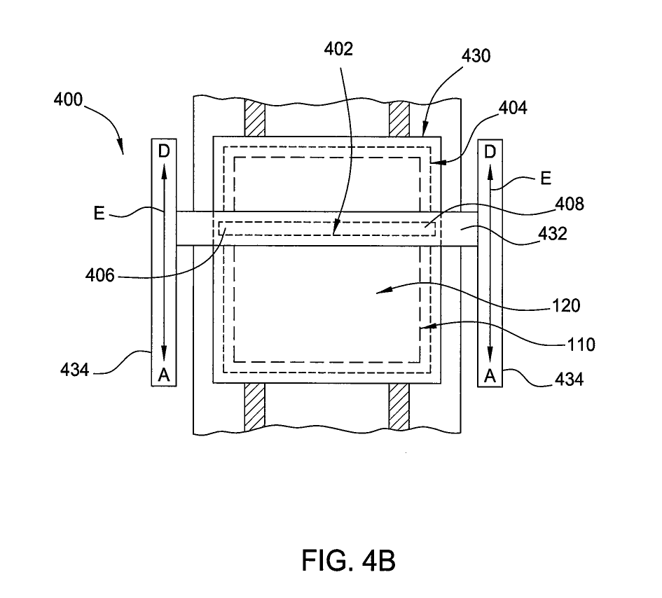

In an alternative embodiment where a squeegee is used as the soft contact tool 308, the etchant 303 may be applied onto the front surface 120 of the substrate 110 using a printing device similar to a screen printing tool, as traditionally used in a screen printing process for applying solder paste. FIG. 4A depicts a side view of an exemplary squeegee blade 402 applying etchant 303 onto a front surface 120 of a substrate 110 using a printing device 400 according to one embodiment of the present invention. For easier understanding, only the squeegee blade 402 and a printing screen 404 are shown in FIG. 4A.

The squeegee blade 402 may be made mobile above the substrate 110 by a slider 432 (FIG. 4B) and may have a longitudinal dimension corresponding to a predetermined dimension of a printing screen surface 404. The squeegee blade 402 may be tilted at an angle θ of about 10° to about 20° with respect to a normal line perpendicular to the front surface 120 of the substrate 110. The squeegee blade 402 may be made of a material that is flexible and resistant to the etchant used in removing the passivation layer 104. For example, polyurethane or other flexible, high-density plastic may be used in making the squeegee blade 402. The printing screen 404 may be made of a piece of porous, finely woven fabric, such as nylon, stretched over a wooden or metallic frame, for example, an aluminum frame.

In this embodiment, the squeegee blade 402 may press etchant 303 against the printing screen 404 which is anchored at two points 406 and 408. Downward pressure is applied to the squeegee blade 402 as the squeegee blade 402 is pulled across the printing screen 404 in the direction of travel indicated as “E”. The etchant 303 is typically introduced in front of the squeegee blade 402, which wipes etchant 303 across mesh openings (not shown) in the printing screen 404. The mesh openings can be formed in a desired pattern to be printed on the substrate 110. As the squeegee blade 402 slidably moves on the upper surface of the printing screen 404, etchant 303 is adhered onto the front surface 120 of the substrate 110 through mesh openings formed in the printing screen 404. The movement of the squeegee blade 402 with respect to the substrate 110 can be better understood in FIG. 4B, which depicts a schematic top view of the printing device 400 located above a substrate 110 placed on the incoming conveyor 212. The printing device 400 as shown generally includes a screen plate 430, a printing screen 404 affixed to the screen plate 430 at two points 406 and 408, a slider 432 holding the squeegee blade 402, and frames 434 for sliding the slider 432 in directions indicated by arrows “E”. In operation, the squeegee blade 402 is moved down, keeping touch with the printing screen 404, and advanced across the front surface 120 of the substrate 110 from a first end A to an opposite end D along the longitudinal direction of the frames 434 to evenly distribute the etchant onto the substrate 110 in a way as discussed above with respect to FIG. 4A. The squeegee blade 402 may travel at a speed relatively faster than the substrate 110 being transported by the incoming conveyor 212. Alternatively, the substrate 110 may remain still while the squeegee blade 402 is moving across the substrate surface.

While not discussed here, it is contemplated that the quantity of etchant 303 deposited may be controlled by, for example, the size of mesh opening, thickness of the fabric screen 404, snap-off distance between the screen 404 and the substrate 110, squeegee angle, and viscosity of the etchant 303, etc. A person skilled in the art may adjust these parameters as necessary to obtain a thin layer of etchant with a uniform thickness (about 10 μm) on the front surface 120 of the substrate 110. Since alignment accuracy is not critical to the deposition of the etchant 303 as would otherwise required in the conventional printing process, the pattern and/or size of the mesh openings may be arbitrary, so long as the etchant 303 can be evenly distributed on entire front surface 120 of the substrate.

Referring back to FIG. 2, after the etchant 303 has been distributed on the front surface 120 of the substrate 110, the substrate 110 is transported by the incoming conveyor 212 to the heating chamber 204 where the etchant 303 is heated using conventional heating approach to dissolve the passivation layer 104 deposited on the periphery region of the substrate 110. The etchant 303 is heated so that a fast exothermic reaction between the etchant 303 and the passivation layer 104 occurs and therefore the etching rate is enhanced. If desired, the substrate support may be rotated relative to the radiant heating sources to average out any non-uniformity in the energy delivered from the radiant heat sources, thereby enhancing the thermal uniformity. The substrate 110 is then rinsed with water or de-ionized water to remove the dissolved passivation layer. Thereafter, the substrate 110 may be dried by passing through an air knife or any other suitable drying approaches such as spin dry, heating, or blow-drying with a dry gas such as nitrogen, argon, or clean dry air.

After the passivation layer 104 has been removed from the front surface 120 of the substrate 110, the substrate 110 is transferred from the heating chamber 204 to the patterning chamber 206 where portions of the passivation layer 104 formed on the back surface 125 are removed to expose a plurality of patterned regions on the back surface 125 of the substrate 110. Through these patterned regions, the metal layer(s) that subsequently deposits on the passivation layer 104 is in intimate contact with the back side of the substrate 110. Typical processes that may be used to pattern the passivation layer 104 may include, but are not limited to, patterning and dry etching techniques, laser ablation techniques, patterning and wet etching techniques, or other similar processes. The patterning chamber 206 may be a laser firing chamber in which a pulsed laser is used to scan across the back surface 125 of the substrate 110, single pulse per contact, and ablate a portion of the passivation layer 104 to create a plurality of patterned regions (i.e., via/contact holes 107 shown in FIG. 1A) in the passivation layer 104. The laser may be a IR wavelength laser, Nd:YAG laser, Nd:YVO₄ laser, or any other suitable laser that is capable of emitting laser radiation at wavelength of 355 nm with a pulse duration of about 80 ns (nanosecond laser) or about 15 ps (picosecond laser). The pulsed laser beam generally has a fluence of about 0.01 J/cm² to about 100 J/cm², for example, about 4.3 J/cm². The laser wavelength or pulse duration may vary depending upon the application. For example, a longer wavelength of 532 nm or 1064 nm may be used if a deeper via/contact hole is desired. Also, a longer time pulse typically spreads energy over a deeper region of the substrate. A single solar cell substrate having a surface area of about 180 mm×180 mm may contain up to 25,000 laser fired contact points, each with a pitch about 1 mm and a diameter of about 50-85 μm.

After the patterned regions (i.e., via/contact holes 107) have been formed in the passivation layer 104 on the back surface 125 of the substrate 110, the substrate 110 may be transferred by the incoming conveyor 212 from the patterning chamber 206 to the substrate support 214a coupled to the rotary actuator assembly 208. The rotary actuator assembly 208 may be rotated and angularly positioned about the “C” axis by a rotary actuator (not shown) and a system controller 220, such that the substrate support may be selectively angularly positioned within the system 200 along paths “D1” and “D2”. In one example shown in FIG. 2, the rotary actuator assembly 208 includes three substrate supports 214a, 214b, 214c that are each adapted to support a substrate 110 during the screen printing process performed within the screen printing chamber 210. The rotary actuator assembly 208 may also have one or more supporting components to facilitate the control of the substrate supports or other automated devices used to perform a substrate processing sequence in the system 200. FIG. 2 schematically illustrates the position of the rotary actuator assembly 208 in which one substrate support 214a is in position “1” to receive a substrate 110 from the incoming conveyor 212, another substrate support 214b is in position “2” within the screen printing chamber 210 so that another substrate 110 can receive a screen printed pattern on a surface thereof, and another substrate support 214c is in position “3” for transferring a processed substrate 110 to the outgoing conveyor 216. If desired, one or more additional substrate supports may be provided to storage substrates in an intermediate stage between position “1” and position “3”.

The screen printing chamber 210 is typically used to deposit material in a desired pattern on the back surface 125 of the substrate 110 positioned on the substrate support 214b in position “2” during the screen printing process. The screen printing chamber 210 is configured to deposit a metal containing material onto the passivation layer 104 on the back surface 125 of the substrate 110 and fill the via/contact holes 107 formed through the passivation layer 104 with the metal containing material, thereby forming the back contact 106. Thereafter, the rotary actuator assembly 208 is rotated and the processed substrate in position “2” within the screen printing chamber 210 is proceeded to position “3” in order to be transferred to the outgoing conveyor 216 for subsequent processes.

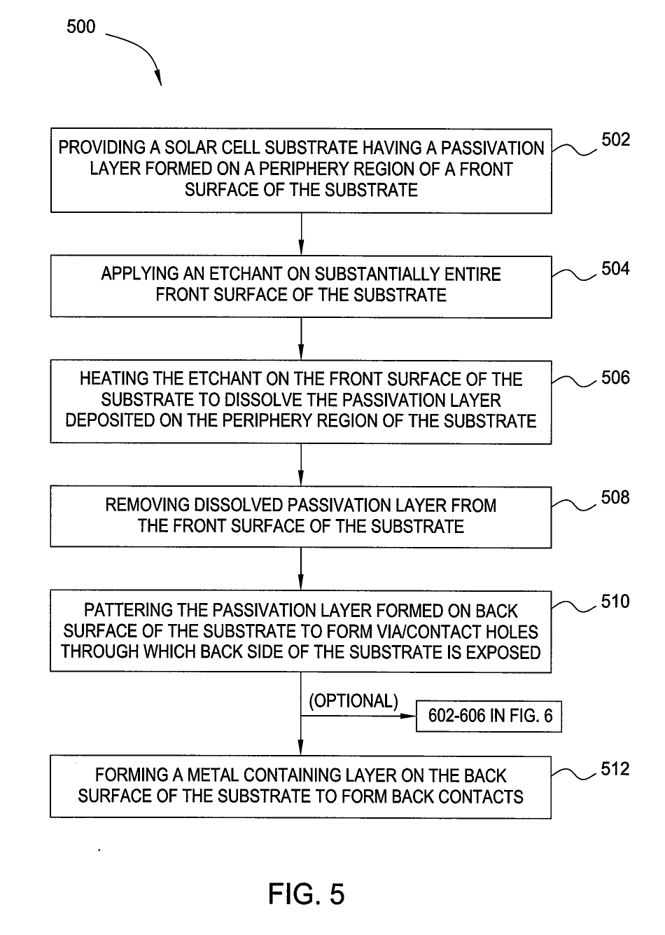

FIG. 5 depicts an exemplary process sequence 500 used to remove a passivation layer from a surface of a solar cell substrate according to one embodiment of the present invention. The process 500 begins at box 502 by providing a solar cell substrate 110 into a processing chamber, for example, a spraying chamber 202 as discussed above with respect to FIGS. 2, 3, and 4A-4B. The substrate 110 to be processed is shown in FIG. 1B. The description thereof is eliminated herein for sake of brevity.

At box 504, an etchant is applied on the entire front surface 120 of the substrate 110. The etchant covers the passivation layer 104 formed on the periphery region of the front surface 120 and the underlying anti-reflective coating layer 111 that is not deposited by the passivation layer 104. The etchant 303 may be applied onto and spread across the front surface 120 of the substrate 110 using the spray device 302 and the soft contact tool 308 in a way as discussed above with reference to FIG. 3, or the printing device shown in FIGS. 4A and 4B, thereby forming a thin etchant layer 307 on the front surface 120 of the substrate 110. The etchant layer 307 may have a thickness which is about a half of the thickness of the substrate 110. The thickness of the etchant layer 307 may vary depending upon the thickness of the passivation layer 104 to be removed from the front surface 120 of the substrate 110. In one example, the etchant layer 307 is about 5 μm to about 20 μm, for example 10 μm in thickness.

In various embodiments of the present invention, the etchant 303 is selectively designed to etch the passivation layer 104 without significantly eroding the underlying anti-reflective coating layer 111. In one example where aluminum oxide (AlₓO_{y}) is used as the passivation layer 104, a suitable etchant 303 may include, but is not limited to, one or more alkaline solutions such as Potassium Hydroxide (KOH), Sodium Hydroxide (NaOH), Ammonium Hydroxide (NH₄OH), Hydrazine Ethylene Diamine Pyrocatechol (EDP), Tetra Methyl Ammonium Hydroxide (TMAH), and all quaternary ammonium hydroxides such as Tetra Ethyl Ammonium Hydroxide (TEAR) and Tetra Propyl Ammonium Hydroxide (TPAH), or other similar alkaline solutions. In one embodiment, the etchant is a dilute solution of potassium hydroxide (KOH) in deionized water. The etchant solution may include KOH at a concentration of about 1% by volume to about 40% by volume, for example, about 4% by volume, and diluted with deionized water. The alkaline solution such as KOH is chosen because the aluminum oxides typically do not withstand the KOH as opposed to the silicon nitrides or silicon oxides. The etchant 303 may also include a surface agent such as polyethylene glycol or polyoxyethylene that promotes effective “printing or applying” of the etchant through the meshing openings of the screen printing mask. A viscosity-increasing agent, for example, glycerol, or aluminum salts such as aluminum phosphate, aluminum chloride, or aluminum sulfate, may be additionally added to the etchant to aid in retention of the etchant on the surface of the substrate 110. In one example, the etchant solution may have a viscosity of about 5-90 Cp, for example, about 50 Cp.

At box 506, the substrate 110 having the thin etchant layer 307 formed on the front surface 120 thereof is transferred by the incoming conveyor 212 to the heating chamber 204 where the substrate 110 is heated to a desired temperature of about 30° C. to about 85° C., for example about 50° C., for about 30 seconds to about 60 seconds. The substrate 110 may be heated using conventional heating approaches such as IR heating elements, IR lamps or flash lamps. The heating causes the chemicals in the etchant to dissolve the passivation layer 104. As the etchant is selective to the passivation layer 104 over the anti-reflective coating layer 111, the heated etchant layer 307 will dissolve the passivation layer 104 deposited on the periphery region of the substrate 110 and does not attack the underlying anti-reflective coating layer 111. In one example where the passivation layer 104 is aluminum oxide and the underlying anti-reflective coating layer 111 is silicon nitride, the etch selectivity of aluminum oxide relative to silicon nitride may be in a range of about 10:1 to about 20:1 or above, for example about 50:1 to about 100:1.

At box 508, after the passivation layer 104 on the periphery region of the substrate 110 has been dissolved, the substrate 110 may be rinsed with water or de-ionized water to remove the dissolved passivation layer 104 from the front surface 120 of the substrate 110. Thereafter, the substrate 110 may be dried by passing through an air knife or any other suitable drying approaches. The rinsing and drying steps may be performed in-situ within the heating chamber 204 or in a cleaning chamber that is independent of the heating chamber.

At box 510, the cleaned substrate 110 is transferred by the incoming conveyor 212 to the patterning chamber 206 where portions of the passivation layer 104 formed on the back surface 125 of the substrate 110 are removed so that the subsequent deposited metal layer(s) can be placed in intimate contact with the back side of the substrate 110 through these patterned regions. The material of the passivation layer 104 may be ablated to obtain via/contact holes (e.g., via/contact holes 107 shown in FIG. 1A) through which the back side of the substrate 110 is exposed. The passivation layer 104 may be ablated by a pulsed laser that is scanned across the back surface 125 of the substrate 110, as discussed above with respect to the patterning chamber 206.

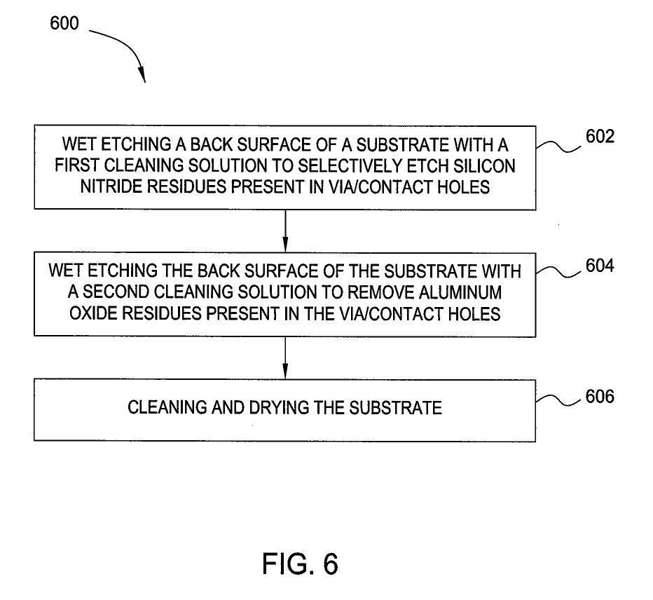

A post-cleaning process may be optionally performed after box 510 to remove debris present in the patterned regions. An exemplary post-cleaning process is further discussed below in the subsequent section entitled “Exemplary Post-Cleaning Process for Via/Contact Holes,” as illustrated in FIG. 6.

At box 512, after the patterned regions (i.e., via/contact holes 107) have been formed in the passivation layer 104 on the back surface 125 of the substrate 110, the substrate 110 may be transferred by the incoming conveyor 212 from the patterning chamber 206 to the screen printing chamber 210 through the rotary actuator assembly 208. The substrate 110 is processed within the screen printing chamber 210 to deposit a metal containing material in a desired pattern onto the passivation layer 104 on the back surface 125 of the substrate 110 and fill the via/contact holes 107 formed through the passivation layer 104 with the metal containing material, thereby forming the back contacts 106. Thereafter, the substrate 110 may be heated to a temperature between about 300° C. and about 800° C. for between about 1 minute and about 30 minutes to assure that a good ohmic contact is formed between the substrate 110 and the back contact 106.

Although the removal of the passivation layer 104 from the front surface 120 of the substrate 110 (i.e., boxes 502-508) is illustrated and described to be performed prior to the laser ablation process (box 510) used to create via/contact holes in the passivation layer 104 formed on the back surface 125, in an alternative embodiment of the present invention the processes described at boxes 502-508 may be performed prior to the screen printing process (box 512), for example, between the laser ablation process (box 510) and the screen printing process (box 512), to achieve the same results without interfering with the deposition of the metal containing material using the screen printing process.

### Exemplary Post-Cleaning Process for Via/Contact Holes

FIG. 6 depicts an exemplary process sequence 600 in accordance with one embodiment of the present invention. The process sequence 600 may be optionally performed between box 510 and box 512 as depicted in FIG. 5 to remove debris, such as ablation residues present in the patterned regions (i.e., via/contact holes 107), resulted from previous patterning process (box 510), damaged base region 121 underneath the passivation layer 104 caused by the laser ablation, or both. These residues or debris could interfere with the subsequent process of forming a high quality metal contact. While the process 600 is illustrated and discussed to be optionally performed between box 510 and box 512, the process 600 may be performed separately to remove debris or residual materials from a surface of any substrate having a layer stack formed of an aluminum oxide (Al₂O₃) and a nitride such as silicon nitride.

The process 600 begins at box 602 by wet etching a surface (e.g., the back surface 125) of the substrate 110 with a first cleaning solution to selectively etch the silicon nitride residues present in the patterned regions (i.e., via/contact holes 107). The silicon nitride residues are formed due to the incomplete ablation from the previous step (i.e., box 510). The substrate 110 may be transferred by the incoming conveyor 212 from the patterning chamber 206 to a cleaning chamber (not shown) disposed between the patterning chamber 206 and the screen printing chamber 210 as depicted in FIG. 2. The wetting is performed in the cleaning chamber and may be accomplished by spraying, flooding, immersing or other suitable techniques.

In one embodiment, the first cleaning solution is a dilute acid solution. The dilute acid solution such as hydrofluoric acid (HF) is chosen because the silicon nitrides or silicon oxides typically do not withstand the HF as opposed to the aluminum oxides. The dilute acid solution is also chosen to minimize the damage to via/contact holes 107 that were already formed in the passivation layer 104. The substrate 110 may be dipped in the dilute acid solution for a period of about 30 seconds to about 800 seconds, followed by a post-rinse step using DI water to clean the substrate surface. In one example, the acid solution is a dilute solution of hydrofluoric acid (HF) in deionized water. The acid solution includes HF at a concentration of about 0.1% by volume to about 5% by volume, for example, about 0.5% by volume to about 1% by volume. The HF dip may be performed at room temperatures (e.g., about 20° C.). The dipping time may vary depending upon the HF concentration and the thickness of the layer to be removed. In cases where the passivation layer 104 is formed as a layer stack comprising an aluminum oxide (Al₂O₃) of about 20 nm in thickness and a silicon nitride (SiN) of about 80 nm in thickness, the substrate 110 may be dipped in a dilute acid solution including HF at a concentration of about 0.5% by volume to about 1% by volume for about 45 seconds to about 70 seconds, such as 60 seconds. An HF wetting provides a cost efficient approach to selectively removing the silicon nitride residues from the back surface 125 of the substrate 110. It is contemplated that other suitable and cost effective cleaning solution such as a dilute ammonium hydroxide (NH₄OH) solution, phosphoric acid (H₃PO₄), a hydrogen peroxide (H₂O₂) solution, or an ozonated water solution may be used.

At box 604, after the silicon nitride residues have been removed from the surface (e.g., the back surface 125) of the substrate 110, the underlying aluminum oxide residues is exposed. The back surface 125 of the substrate is then wet etched with a second cleaning solution to remove the aluminum oxide residues. The removal of the aluminum oxide residues may be performed in situ in the cleaning chamber used to remove the silicon nitride residues, or in a separate cleaning chamber. Similarly, the wetting may be accomplished by spraying, flooding, immersing or other suitable techniques.

In one embodiment, the second cleaning solution is a dilute alkaline solution. The substrate 110 may be dipped in the dilute alkaline solution for a period of about 5 seconds to about 200 seconds, followed by a post-rinse step using DI water to clean the substrate surface. In one example, the alkaline solution is a dilute solution of potassium hydroxide (KOH) in deionized water. The alkaline solution includes KOH at a concentration of about 0.5% by volume to about 5% by volume, for example, about 2% by volume to about 3% by volume. The KOH dip may be performed at a temperature of about 40° C. to about 95° C., for example about 85° C. The dipping time may vary depending upon the KOH concentration and the thickness of the layer to be removed. In cases where the passivation layer 104 is formed as a layer stack comprising an aluminum oxide (Al₂O₃) of about 20 nm in thickness and a silicon nitride (SiN) of about 80 nm in thickness, the substrate 110 may be dipped in a dilute alkaline solution including KOH at a concentration of about 2% by volume for about 30 seconds to about 60 seconds. A KOH wetting provides a cost efficient approach to selectively removing the aluminum oxide residues from the back surface 125 of the substrate 110 without significantly eroding the underlying p-type base region 121. It is contemplated that other alkaline solutions such as sodium hydroxide (NaOH), ammonium hydroxide (NH₄OH), hydrazine ethylene diamine pyrocatechol (EDP), or tetra methyl ammonium hydroxide (TMAH) may be used.

To prevent damage to the underlying p-type base region 121, a sensor may be used to detect an endpoint of etching of the aluminum oxide residues. As aluminum oxide etching in aqueous KOH or similar alkaline solutions is accompanied by hydrogen gas evolution due to the following equation (a), these hydrogen bubbles may serve as an endpoint indicating that the KOH has reached the underlying p-type base region 121 (e.g., silicon substrate).

Si+2OH⁻+4H₂O->Si(OH)₂²⁺+2H₂+4OH⁻ (a)

The detection of this hydrogen bubbles may be achieved by using an acoustic sensor because hydrogen bubbles start making noise when it is bubbling. Alternatively, conventional sensors such as a H₂ sensor, a bubble sensor, an optical sensor, or any suitable sensors may be used to detect the etching end point.

At box 606, after the aluminum oxide residues have been removed from the back surface 125 of the substrate 110, the substrate 110 may be dried by passing through an air knife or any other suitable drying approaches such as spin dry, heating, or blow-drying with a dry gas such as nitrogen, argon, or clean dry air. The dried substrate 110 may be transferred by the incoming conveyor 212 from the cleaning chamber (not shown) to the screen printing chamber 210 through the rotary actuator assembly 208, as discussed above with respect to box 512.

The two-step post-cleaning process discussed herein has been observed to be able to improve series resistance by removing silicon nitride and aluminum oxide residues present in the patterned regions (i.e., via/contact holes 107). The cleaned surface within the patterned regions is obtained so that a reliable backside electrical contact can be formed in these areas in the following process at box 512. Crystalline Si photovoltaic cells with rear passivation films have shown high sensitivity to the post-cleaning process. The crystalline Si photovoltaic cells cleaned according to embodiments described herein may exhibit cell efficiency from 14.9% average without the post-clean to over 18% average with the post-clean, and fill factor (FF) from 71% average without the post-clean to over 77% average with the post-clean. The cell efficiency and FF results correlated with open circuit resistance (Roc) values, which suggests that the post-cleaning process helps to improve series resistance by cleaning out the interfering residues present in the patterned regions.

While the foregoing is directed to embodiments of the present invention, other and further embodiments of the invention may be devised without departing from the basic scope thereof, and the scope thereof is determined by the claims that follow.

1. A method of processing a solar cell substrate, comprising:
providing a substrate having a passivation layer deposited on a first surface of the substrate, the passivation layer being formed as a layer stack comprising a first layer and a second layer, and the first layer is different from the second layer;
exposing the first surface of the substrate to an etchant;
heating the etchant to dissolve the first layer of the passivation layer on the first surface;
forming a metal containing layer on a second surface of the substrate, the second surface being opposite to the first surface.

2. The method of claim 1, wherein the first layer and the second layer are selected from the group consisting of aluminum oxide, aluminum nitride, aluminum oxynitride, silicon oxide, silicon nitride, amorphous silicon, and amorphous silicon carbide.

3. The method of claim 1, wherein the etchant is a dilute alkaline solution comprising Potassium Hydroxide (KOH), Sodium Hydroxide (NaOH), Ammonium Hydroxide (NH₄OH), Hydrazine Ethylene Diamine Pyrocatechol (EDP), Tetra Methyl Ammonium Hydroxide (TMAH), Tetra Ethyl Ammonium Hydroxide (TEAH), Tetra Propyl Ammonium Hydroxide (TPAH), or combination thereof.

4. The method of claim 3, wherein the dilute alkaline solution includes KOH at a concentration of about 1% by volume to about 40% by volume.

5. The method of claim 1, wherein the etchant further comprises polyethylene glycol, polyoxyethylene, glycerol, aluminum phosphate, aluminum chloride, or aluminum sulfate.

6. The method of claim 5, wherein the etchant has a viscosity of about 5-90 Cp.

7. The method of claim 1, wherein the etchant is heated to a temperature of about 30° C. to about 85° C. for about 30 seconds to about 60 seconds.

8. The method of claim 2, wherein the first layer is aluminum oxide and the second layer is silicon nitride, and the etchant has an etch selectivity of the aluminum oxide relative to silicon nitride in a range of about 10:1 to about 100:1.

9. The method of claim 1, further comprising:
prior to the formation of the metal containing layer, forming via/contact holes in a passivation layer deposited on the second surface.

10. The method of claim 1, wherein the exposing the first surface of the substrate to the etchant further comprises:
applying the etchant onto the first surface of the substrate; and
spreading the etchant across the entire first surface through a linear and/or circular movement of a roller.

11. The method of claim 1, wherein the exposing the first surface of the substrate to the etchant further comprises:
pressing the etchant against a printing screen having a plurality of mesh openings formed therethrough using a soft contact tool; and
wiping the etchant across the printing screen to apply the etchant onto the first surface through the mesh openings.

12. A method of processing a solar cell substrate, comprising:
providing a substrate having a passivation layer deposited on a surface of the substrate, the passivation layer being formed as a layer stack comprising an aluminum oxide and a silicon nitride deposited on the aluminum oxide;
forming a plurality of via/contact holes in the passivation layer to expose the underlying surface of the substrate;
exposing the substrate to a first cleaning solution comprising a dilute acid solution to selectively remove a portion of silicon nitride present in the formed via/contact holes;
exposing the substrate to a second cleaning solution comprising a dilute alkaline solution to selectively remove a portion of aluminum oxide present in the formed via/contact holes; and
forming a metal containing layer on the surface of the substrate, wherein the metal containing layer fills the plurality of formed via/contact holes and is in intimate contact with the underlying surface of the substrate through the via/contact holes.

13. The method of claim 12, wherein the dilute acid solution comprises hydrofluoric acid (HF) at a concentration of about 0.1% by volume to about 5% by volume.

14. The method of claim 12, wherein the substrate is exposed to the first cleaning solution at about 20° C. for about 45 seconds to about 70 seconds.

15. The method of claim 12, wherein the dilute alkaline solution comprises potassium hydroxide (KOH) at a concentration of about 0.5% by volume to about 5% by volume.

16. The method of claim 15, wherein the substrate is exposed to the second cleaning solution at about 40° C. to about 95° C. for about 30 seconds to about 60 seconds.

17. A processing system for processing a substrate, comprising:
a spraying chamber having a spray device configured to supply an etchant onto a first surface of the substrate;
a heating chamber having a radiant heating source configured to heat the etchant to dissolve a passivation layer deposited on the first surface of the substrate, the passivation layer comprising aluminum oxide;
a patterning chamber configured to deliver a pulsed laser scanning across a surface of a passivation layer deposited on a second surface of the substrate, the second surface being opposite to the first surface, and the passivation layer being formed as a layer stack comprising an aluminum oxide and a silicon nitride deposited on the aluminum oxide;
a screen printing chamber configured to deposit a metal containing layer in a predetermined pattern on the passivation layer deposited on the second surface of the substrate; and
a transport system for conveying the substrate through the spraying chamber, the heating chamber, the patterning chamber, and the screen printing chamber.

18. The system of claim 17, further comprising:
a cleaning chamber configured to sequentially remove a portion of the silicon nitride and the aluminum oxide from the second surface, the cleaning chamber comprising:
a first tank containing a dilute acid solution comprising hydrofluoric acid (HF) at a concentration of about 0.1% by volume to about 5% by volume; and
a second tank containing a dilute alkaline solution comprising potassium hydroxide (KOH) at a concentration of about 0.5% by volume to about 5% by volume.

19. The system of claim 17, wherein the spraying chamber further comprises:
a printing screen disposed between the spray device and the substrate, the printing screen having a plurality of mesh openings formed therethough; and
a soft contact tool configured to press against and wipe the etchant across the printing screen to deposit the etchant onto the surface through the plurality of mesh openings.

20. The system of claim 17, wherein the soft contact tool comprises a blade, squeegee, brush, or the like.
